(19) United States
(12) Patent Application Publication
(10) Pub. No.: US 2009/0000110 A1
(43) Pub. Date: Jan. 1, 2009

(54) Mounting Method and Component Mounter

(76) Inventor: Yasuhiro Maenishi, Saga (JP)

Correspondence Address: WENDEROTH, LIND & PONACK L.L.P., 2033 K. STREET, NW, SUITE 800, WASHINGTON, DC, 20006, US

(21) Appl. No.: 12/279,099

(22) PCT Filed: Feb. 22, 2007
(86) PCT No.: PCT/JP2007/053845

§ 371 Date: Aug. 12, 2008

(30) Foreign Application Priority Data
Feb. 27, 2006 (JP) 2006-051245

(51) Int. Cl. H05K 3/30

(52) U.S. Cl. 29/743; 29/739; 29/832

(57) ABSTRACT

A component mounting method including recover processing appropriate for use in a modular-type component mounter.

The component mounting method is for use in a component mounter which includes a multi-nozzle mounting head for picking up plural components, holding the components at one time, and attaching the picked-up components in sequence on a board, and the component mounting method includes: acquiring mounting operation information; judging, based on the acquired mounting operation information, whether or not a component has been mounted properly; and in the case where the component is judged as not having been mounted properly, performing recovery by re-mounting the component not mounted properly, before moving to the task that follows the task in which the component was not mounted properly (S211 to S213). The task is defined as one iteration of a process that includes the series of pickup, transport, and attachment of a component by a multi-nozzle mounting head.

### TECHNICAL FIELD

The present invention relates to a mounting method and the like applied in a component mounter which mounts components on a board, and particularly relates to a mounting method that includes recovery processing when a mounting error, such as a missing component, occurs on the board during the mounting process.

### BACKGROUND ART

Mounting errors occur with a certain probability during the operational series of picking up, moving, and attachment of electronic components performed by a component mounter. “Missing components,” where an electronic component to be attached on the board is not attached, such as when the electronic component fails to be taken from a component supply unit or the picked-up electronic component is dropped during transport from the component supply unit to the position where it is to be attached, and “standing pickup,” where the pickup nozzle does not make proper contact with the surface of the component and picks it up in a vertical or angled state, can be given as examples of such mounting errors.

Conventionally, when such a mounting error occurs, in order to make a recovery without stopping the component mounter, the mounting error is ignored and the mounting process continued, and the mounting of the electronic component for which the mounting error occurred is performed again after the final component in the mounting program has been mounted.

However, with the increased miniaturization of electronic devices, miniaturization and high performance have come to be demanded in regards to circuit boards. Hence there are cases where components are very densely mounted on circuit boards, or in other words, the space between electronic components mounted on the board is extremely small; therefore, when re-mounting an electronic component for which a mounting error has occurred after the series of mounting operations has finished, there are cases where the already-attached electronic components interfere with the tip of the nozzle that holds the electronic component for which re-mounting is to be performed, and mounting error recovery cannot be completed.

In response to this problem, a technique has been disclosed by which the electronic components to be mounted are divided into groups by height, the electronic components are mounted in order from the shortest to the tallest component, and mounting error recovery is performed for the height group in which the error occurred after the mounting of that height group finishes and before the electronic components of the next height group are mounted (for example, see Patent Reference 1: Japanese Patent No. 3,043,492).

However, recent component mounters themselves have become more compact and footprint-to-productivity ratios have increased, and thus modular-type component mounters, which employ multi-nozzle mounting heads that can pick up and hold a number of electronic components, have become widespread. With such modular-type component mounters, a number of electronic components are held by a multi-nozzle mounting head and are collectively transported to above the board, and after this, the electronic components are attached in order while the multi-nozzle mounting head moves above the board. Therefore, in such modular-type component mounters, the aforementioned method of grouping the electronic components by height and performing error recovery on a per-group basis lacks flexibility.

With such modular-type component mounters, a single iteration of the operational series of picking up, moving, and attaching a component as performed by the multi-nozzle mounting head, or the group of components transferred in the single iteration of the operational series, are referred to as a “task.” A task in which the number of times the multi-nozzle mounting head moves (the number of tasks) is a minimum is then generated, and the mounting order is determined.

Therefore, when a mounting error occurs, the number of times the multi-nozzle mounting head must move increases due to the recovery process, despite the task being determined so that the number of times the multi-nozzle mounting head moves is a minimum; accordingly, there is the possibility that the state of subsequent tasks degenerates and the lost time for mounting increases.

Accordingly, when a mounting error occurring within a task, it is imperative that the influence of that error (in other words, the tact loss) be limited to that task alone, and that subsequent tasks not be affected by the error.

Having been conceived in light of the above problems, an object of the present invention is to provide a mounting method which performs mounting error recovery favorable for use in a modular-type component mounter.

### DISCLOSURE OF INVENTION

To achieve the above-mentioned object, the component mounting method according to the present invention is a component mounting method for use in a component mounter which includes a multi-nozzle mounting head for picking up plural components, holding the components at one time, and attaching the picked-up components in sequence on a board, and includes: acquiring mounting operation information; judging, based on the acquired mounting operation information, whether or not a component has been mounted properly; and in the case where the component is judged as not having been mounted properly, performing recovery by re-mounting the component not mounted properly, before moving to the task that follows the task in which the component was not mounted properly. The task is defined as one iteration of a process that includes the series of pickup, transport, and attachment of a component by a multi-nozzle mounting head.

This mounting method includes recovery processing that is favorable for use in a modular-type component mounter that includes a multi-nozzle mounting head.

It should be noted that the phrase “mounting operation information,” which appears in the specification and claims of the present invention, is a concept that includes the state of an attached component, a state in which a component that should have been attached is missing, and the state of the end of a nozzle.

Furthermore, the phrase “attachment state of a component” or simply “attachment state” is a concept that includes a state in which a component has been successfully attached, states in which the component is off-position or is in a state differing from a predetermined attachment state (standing attachments, floating leads (leads not being attached properly), and so on), a state in which a component has not been attached, and so on.

Moreover, in the case where plural components are judged as not having been mounted properly in said judging, in said recovery, it is preferable for the plural components not mounted properly to be held and re-mounted collectively after the task in which the improper mounts occurred finishes.

Through this, it is possible to bring the number of times the multi-nozzle mounting head transits from the component supply unit to the board and back again for error recovery down to one, and thus possible to keep the amount of lost mounting time low while not greatly disturbing the state of the task.

Note that the abovementioned object may be achieved by employing a program which causes a computer to execute the aforementioned steps, and the same effect as described earlier can be realized through a component mounter which includes the aforementioned steps as executable units.

Accordingly, it is possible to provide a mounting method which performs mounting error recovery favorable for use in a modular-type component mounter.

Further Information about Technical Background to this Application

The disclosure of Japanese Patent Application No. 2006-51245 filed on Feb. 27, 2006 including specification, drawings and claims is incorporated herein by reference in its entirety.

### BRIEF DESCRIPTION OF DRAWINGS

These and other objects, advantages and features of the invention will become apparent from the following description thereof taken in conjunction with the accompanying drawings that illustrate a specific embodiment of the invention. In the Drawings:

FIG. 1 is a perspective showing the exterior of a component mounter embodying the present invention, with a part cut away.

FIG. 2 is a plane view showing the primary configuration of the component mounter.

FIG. 3 is a perspective showing a multi-nozzle mounting head.

FIG. 4A is a side view of a multi-nozzle mounting head; FIG. 4B is a bottom view of the multi-nozzle mounting head; and FIGS. 4C and 4D are enlarged top views of an electronic component 300.

FIG. 5 is a block diagram showing a functional configuration of a mount state judgment device.

FIG. 6 is a flowchart showing a process for checking the mount state.

FIGS. 7A, 7B, and 7C show a sequence of side views occurring when attaching an electronic component to a board.

FIG. 8 is a diagram conceptually and schematically showing image synthesis processing.

FIG. 9 is a flowchart showing a processing operation for determining a mounting defect.

FIG. 10 is a flowchart showing an operation through which a judgment unit calculates the degree to which a component is off-position and through which the quality of a mount state is judged based on the degree to which the component is off-position.

FIGS. 11A, 11B, and 11C are diagrams showing a positional relationship for an electronic component.

FIG. 12 is a block diagram showing a control unit which controls recovery processing.

FIG. 13 is a flowchart showing an operation performed in recovery processing.

FIG. 14A is a diagram schematically showing a state in which a mounting abnormality has occurred, and FIG. 14B is a diagram showing a recovery task.

FIG. 15 is a plane view showing the primary configuration of a component mounter which can perform alternating mounting.

FIGS. 16A, 16B, 16C, and 16D are diagrams showing the timing at which error recovery is performed in a component mounter which can perform alternating mounting.

### BEST MODE FOR CARRYING OUT THE INVENTION

### First Embodiment

Hereafter, an embodiment of the present invention shall be described with reference to the drawings.

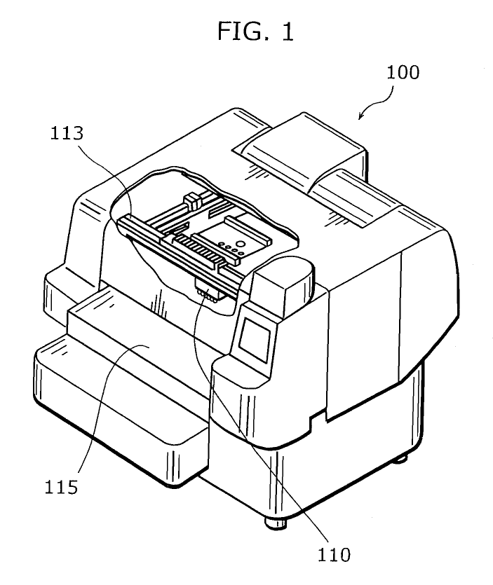

FIG. 1 is a strabismus diagram showing the exterior of a component mounter 100 embodying the present invention, with a part cut away.

The component mounter 100 shown in FIG. 1 is a device which can be incorporated into a mounting line, and is a device which attaches electronic components on a board received from further up the mounting line and passes the board that has had components attached to it, or the mounted board, down the mounting line. The component mounter 100 includes: a multi-nozzle mounting head 110, which has pickup nozzles which pick up and hold electronic components through vacuum suction, and plural attachment heads which can transport the picked up electronic components and attach them to the board; an XY robot 113 which moves the multi-nozzle mounting head 110 on a horizontal plane; and a component supply unit 115 which can sequentially supply the electronic components held in multiple.

To be more specific, the component mounter 100 is a fine-pitch multi-function device which can attach various types of electronic components on a board at high speed; examples of these electronic components include connectors from minute components, large electronic components (more than 10 mm²), irregularly-shaped components such as switches and connectors, IC components such as quad flat packages (QFPs) and ball grid arrays (BGAs), and so on. Note that the present embodiment indicates a single embodiment of the present invention, and the term “fine-pitch multi-function device” used here is nothing more than a term used to indicate an example of the “component mounter” referred to in the claims. In other words, the term “component mounter” should be broadly interpreted; devices (machines) which mount components onto a board are included in the definition of “component mounters.”

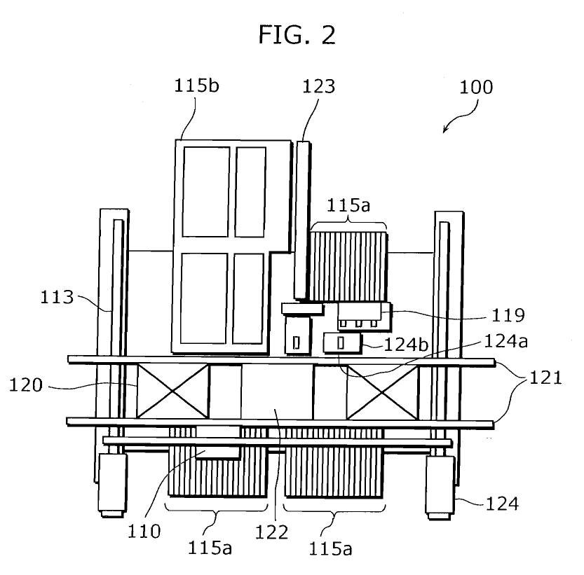

FIG. 2 is a plane view showing the primary configuration of the component mounter 100.

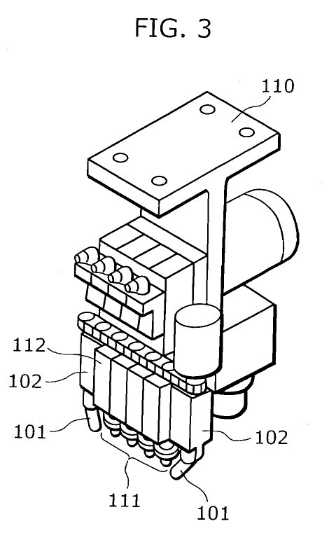

The component mounter 100 further includes: a nozzle station 199, which holds replacement pickup nozzles that can be freely interchanged on the multi-nozzle mounting head 110 (see FIG. 3) to adapt to various types of component shapes; a rail 121, which makes up a transport track for a board 120; an attachment table 122 on which the transported board 120 is placed while the electronic components are attached thereto; a component collection device 123 which collects failed components that have been picked up by the pickup nozzle prior to the components being attached; and a recognition device 124 which images the electronic components held by the pickup nozzles prior to the components being attached and provides the image obtained thereby for use in image analysis.

The recognition device 124 is a device which images the electronic components held by the pickup nozzles prior to the components being attached, and acquires deviation in the X, Y, and θ directions of the electronic components relative to the pickup nozzle based on the position of the pickup nozzle and the image of the electronic components. The component mounter 100 according to the present embodiment has, as the recognition device 124, a CCD camera-type recognition device 124a which images the electronic components and obtains an image of the pre-attachment electronic components from the bottom, and a line sensor-type recognition device 124b which illuminates the electronic components with a laser beam and obtains a stereoscopic image of the pre-attachment electronic components from the bottom based on the reflected light.

In particular, the line sensor-type recognition device 124b can stereoscopically track the electronic components from beneath the components, and thus the cause of mounting errors, such as abnormal curves in electronic component leads, electrode defects, and so on can be detected.

The component supply unit 115 is provided in the front and back of the component mounter 100, and includes a component supply unit 115a, in which a number of tape feeders that sequentially supply electronic components arranged and held in a column on continuous tape are arranged in a line, and a component supply unit 115b, which supplies electronic components stored in a matrix in a plate.

FIG. 3 is a perspective showing the multi-nozzle mounting head 110.

As can be seen in FIG. 3, the multi-nozzle mounting head 110 has plural attachment heads, and a pickup nozzle 111 is provided in each attachment head. In addition, mount point cameras 101, for imaging the attachment state of the attached electronic components 300, are installed on both sides of the multi-nozzle mounting head 110.

Note that in the embodiment of the present invention, the term “mount point camera” is used so as to distinguish the mount point camera from the camera found in the aforementioned recognition device 124. In other words, the term “mount point” is not intended to limit the scope of the present invention, and is used merely when referring to a camera for imaging the vicinity of and directly above a mount point.

The pickup nozzle 111 is a member which holds electronic components through vacuum suction, and can freely extend and retract. The tip of the pickup nozzle 111 is configured of metal, and furthermore, the surface of the tip of the pickup nozzle 111 has a diamond film or the like binded to it with a carbide in order to prevent abrasion through contact with the electronic components.

The mount point camera 101 is a digital camera configured of an imaging element such as a CCD or a CMOS and a lens, and is installed on the multi-nozzle mounting head 110 via a camera holding part 102.

The camera holding part 102 includes, internally, a driving unit including a drive source and a drive mechanism, and can cause the mount point camera 101 it holds to tilt, rotate, and so on via external control.

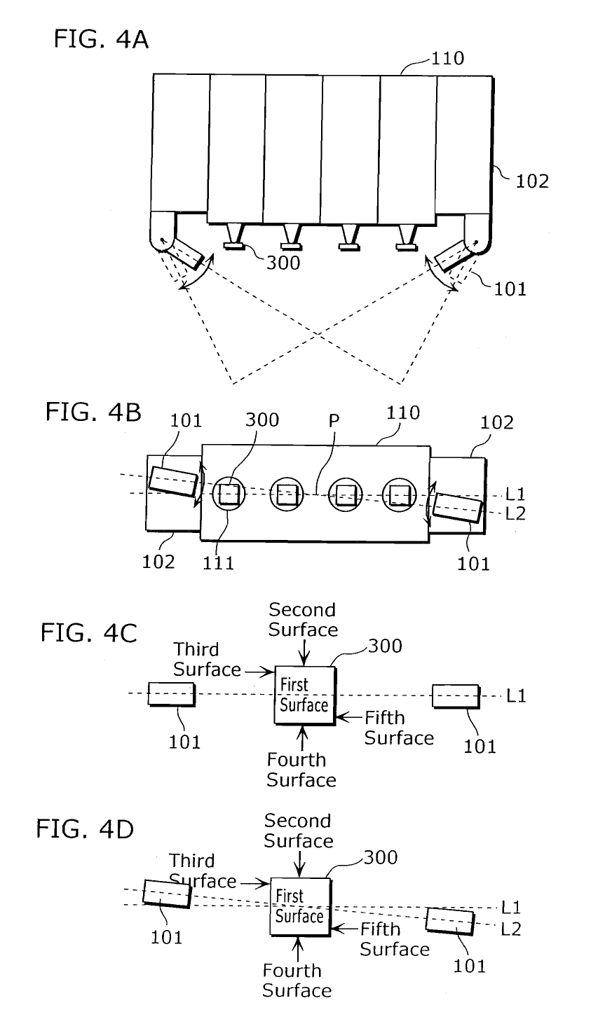

FIG. 4A is a side view of the multi-nozzle mounting head 110; FIG. 4B is a bottom view of the multi-nozzle mounting head 110; and FIGS. 4C and 4D are enlarged top views of an electronic component 300.

Two mount point cameras 101 respectively installed on either side of the multi-nozzle mounting head 110 tilt in the mariner shown in FIG. 4A via the driving unit included in the camera holding parts 102, and can image any of the pickup nozzles 111 attaching an electronic component 300.

Furthermore, as shown in FIG. 4B, the two mount point cameras 101 are not positioned above a straight line L1 which follows the arrangement of the pickup nozzles 111; rather, the two mount point cameras 101 are arranged so that the line L1 which follows the arrangement of the pickup nozzles 111 and a line L2 which connects the two mount point cameras 101 intersect with one another.

In addition, the two mount point cameras 101 are arranged so that an intersect P, which is the point where L1 and L2 intersect, exists between the two mount point cameras 101 and between the pickup nozzle 111 present at one end and the pickup nozzle 111 present at the other end.

Accordingly, the electronic component 300 can be imaged from various angles (on the horizontal plane).

In other words, for example, the electronic component 300 is assumed to be quadrangular, and in the case where the quadrangle is attached so that one side is parallel to the line L1 on which the pickup nozzles 111 are arranged, as can be seen in FIG. 4C, image information can be obtained for the first, third, and fifth surfaces when the two mount point cameras 101 are arranged along the line L1 on which the pickup nozzles 111 are arranged, but image information cannot be obtained, or is difficult to obtain, for the second and fourth surfaces.

On the other hand, as can be seen in FIG. 4D, in the case where the electronic component 300 is imaged from various angles (on the horizontal plane) through the arrangement of the present embodiment, it is possible for one of the two mount point cameras 101 (the one on the left in FIG. 4D) to image the first, second, and third surfaces of the electronic component 300, and for the other mount point camera 101 (the one of the right in FIG. 4D) to image the first, fourth, and fifth surfaces of the electronic component 300. Therefore, the image information of the electronic component that can be acquired by the two mount point cameras 101 at a single time increases, and thus even when an abnormality arises in, for example, one a single surface of the electronic component, such as the second surface, that abnormality can be detected.

However, in the case where the electronic component 300 is quadrangular, and is attached in a state in which one side of the quadrangle is parallel to the line L2 that connects the two mount point cameras 101, the state becomes as shown in FIG. 4C, and only image information of the first, third, and fifth surfaces of the electronic component 300 can be acquired. Still, generally speaking, the electronic components 300 are in most cases attached in a state in which their sides are parallel or perpendicular to the line L1 on which the pickup nozzles 111 are arranged, and thus it is preferable for the two mount point cameras 101 to be arranged on opposite sides of the line L1 on which the pickup nozzles 111 are arranged.

Note that the aforementioned description is not intended to dismiss the idea of arranging both the pickup nozzles 111 and mount point cameras 101 on a straight line. In the case of arranging the pickup nozzles 111 and the mount point cameras 101 on a straight line, it is not necessary for the mount point cameras 101 to rotate on the horizontal plane; the mount point cameras 101 may simply tilt on a single axis.

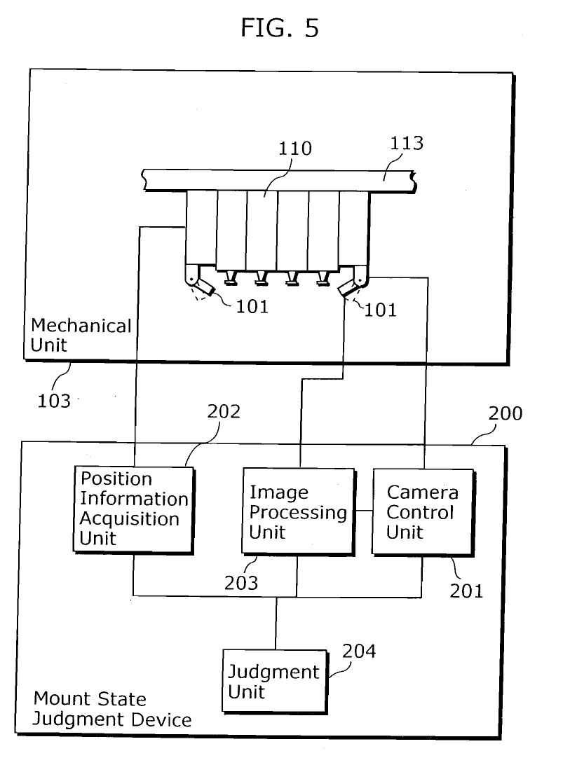

FIG. 5 is a block diagram showing a functional configuration of a mount state judgment device 200, which judges mounting operation information.

As shown in FIG. 5, the mount state judgment device 200 is a computer which judges whether or not the mount state is acceptable while exchanging information with the mechanical unit 103 of the component mounter 100, and includes: a camera control unit 201, which functions as an imaging control means; a position information acquisition unit 202; an image processing unit 203; and a judgment unit 204.

The camera control unit 201 is a processing unit which acquires a signal indicating that the pickup nozzle 111 has retracted after attaching the electronic component 300 on the board 120, and synchronizes the mount point cameras 101 to the signal or controls the mount point cameras 101 so as to perform imaging immediately after acquisition of the signal. In addition, the mount point cameras 101 can perform imaging as many times and from as many angles as necessary up until the acquisition of a signal indicating that the pickup nozzle 111 has reached a certain upper limit, or in other words, that the pickup nozzle 111 has been fully stored within the multi-nozzle mounting head 110.

Furthermore, the camera control unit 203 can independently control the respective driving units within the two camera holding parts 102 installed on either side of the multi-nozzle mounting head 110, cause the mount point cameras 101 to tilt or rotate, and can control the two mount point cameras 101 SO as to constantly view the area surrounding the mount point. The camera control unit 201 also has a function for acquiring information of the tilt and rotation angles of the mount point cameras 101 when imaging the mount state, which is one piece of the mounting operation information.

The position information acquisition unit 202 is a processing unit which acquires position information, within the horizontal plane, of the pickup nozzle 111 which has descended from the attachment head and is performing operations for attaching the electronic components 300 on the board 120. The position information is stored based on information from an encoder provided in the XY robot 113 and the position of the pickup nozzle 111 in the multi-nozzle mounting head 110. Note that the information may be information of the mount point acquired by the component mounter 100 in advance.

The image processing unit 203 is a processing unit which processes the image information obtained from the mount point cameras 101 and the skew between the images of the electronic components 300 filmed based on the tilt and rotation angles of the mount point cameras 101 and synthesizes an image.

The judgment unit 204 is a processing unit which judges whether or not the mount state is acceptable based on the image processed by the image processing unit 203. In addition, the judgment unit 204 also has a function for analyzing the image and calculating the degree to which the electronic component 300 is off-position. Note that the judgment method and the method for calculating the degree to which the component is off-position shall be described later.

Next, a general outline of the operation for mounting a component as performed by the above-described component mounter 100 shall be given.

First, (1) the multi-nozzle mounting head 110 moves to above the component supply unit 115, and each pickup nozzle 111 picks up and holds the desired electronic component 300. Next, (2) the electronic component 300 is transported to above the recognition device 124 and the state in which the electronic component 300 is being held is checked. Then, (3) the multi-nozzle mounting head 110 sequentially moves so that each pickup nozzle 111 is positioned above the respective mount points; the electronic components 300 held by each pickup nozzle 111 are then caused to descend in order starting with the pickup nozzle 111 positioned above the mount point, and the electronic components 300 are attached to the board 120 in such a manner. Finally, (4) when the attachment of the electronic components 300 (in the present embodiment, a maximum of four components) held by the multi-nozzle mounting head 110 finishes, the multi-nozzle mounting head 110 returns to the component supply unit 115 to pick up new electronic components 300.

The electronic components 300 are mounted on the board 120 by repeating the above (1) through (4). Note that there are cases in the present specification in which the above operations (1) through (4), or the components transferred through an iteration of those operations, are referred to as a “task.”

Next, a method for checking the mount state, which is one piece of mounting operation information, shall be described.

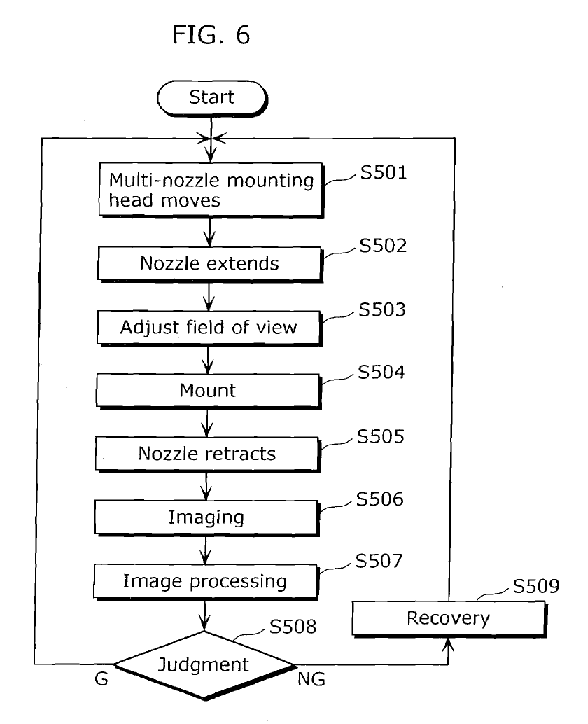

FIG. 6 is a flowchart showing a process for checking the mount state.

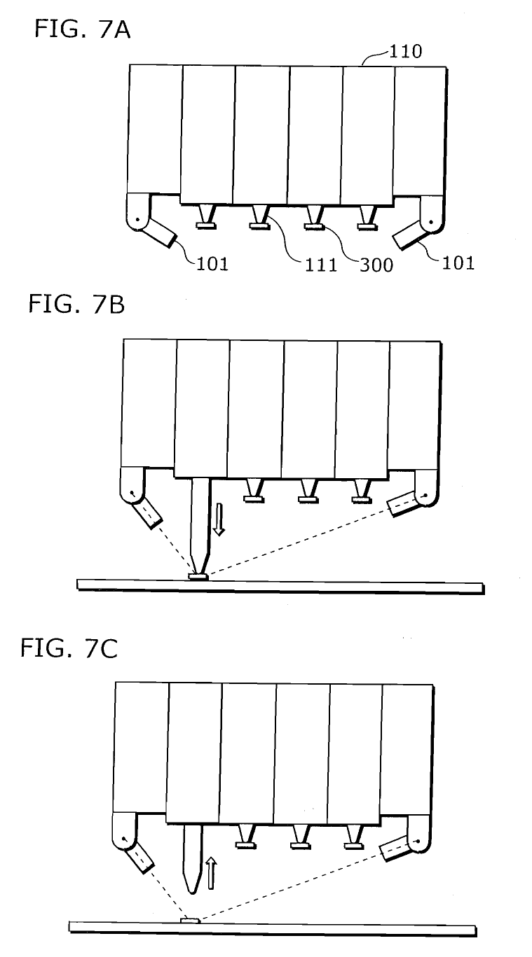

FIG. 7 is a sequence of side views occurring when attaching an electronic component 300 onto a board 120.

First, the multi-nozzle mounting head 110, which has picked up a predetermined number of electronic components 300 from the component supply unit 115, decelerates and comes to a stop above the mount point on the board 120 (S501, FIG. 7(a)).

Next, a pickup nozzle 111 begins to extend so as to attach the electronic component 300 it holds to the board 120 (S502, FIG. 7 (b)).

While the pickup nozzle 111 is extending, the mount point cameras 101 on either side of the multi-nozzle mounting head 110 adjust their respective fields of view (S503). To be more specific, in the state shown in FIG. 7(b), the pickup nozzle 111 on the far left of the multi-nozzle mounting head 110 extends and attaches the electronic component 300 it holds to the board 120; therefore, the camera control unit 201 controls the tilt and rotation angles of the mount point cameras 101 so as to cover the attachment position (mount point) of the electronic component 300 being mounted.

Next, after the electronic component 300 has contacted the board 120, the pickup nozzle 111 is retracted while applying positive pressure within the pickup nozzle 111 (performing “blowing”) (S505, FIG. 7(c)).

The two mount point cameras 101 perform imaging in synchronization with the timing of the pickup nozzle 111 being retracted (S506, FIG. 7(c)). The images obtained through this imaging are obtained in synchronization with the timing of the pickup nozzle 111 being retracted, and therefore images of the electronic component 300 and the tip of the pickup nozzle 111 are captured at the same time. Note that there are cases in which an image of the electronic component 300 cannot be obtained, such as the case where the multi-nozzle mounting head 110 drops the electronic component 300 during transport (S501).

Next, during the time in it takes for the pickup nozzle 111 to reach the upper limit, the image processing unit 203 synthesizes the two images obtained from the mount point cameras 101 (S507), and judges whether or not the mount state is acceptable based on the processed image (S508). Note that details of the synthesis processing and judgment processing shall be given later.

If the judgment results indicate that the mount state is acceptable (G in S508), the multi-nozzle mounting head 110 moves in order to perform the next mounting or to pick up a new electronic component 300.

If the judgment results indicate that the mount state is unacceptable (NG in S508), recovery processing is performed. Details of the recovery processing shall be given later.

Next, the image synthesis processing performed by the image processing unit 203 shall be described.

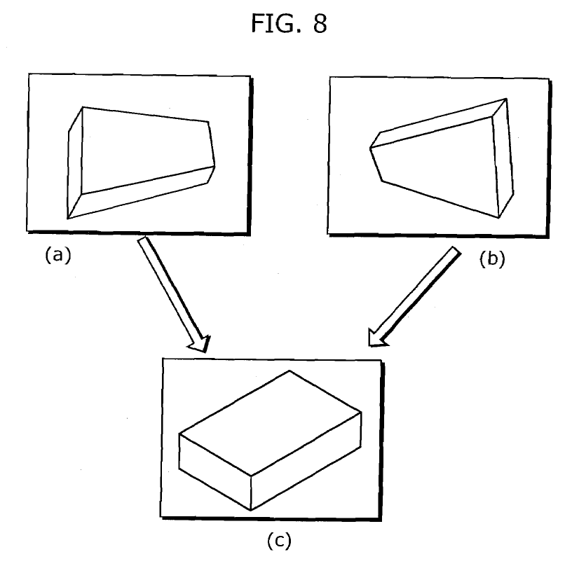

FIG. 8 is a diagram conceptually and schematically showing the image synthesis processing.

For example, in the case where the electronic component 300, which is a quadrangle, is imaged by the mount point cameras 101, two differing images in states of distortion caused by the distance and angles between the mount point cameras 101 and the electronic component 300 are obtained; examples of these distorted images can be seen in (a) and (b) of FIG. 8.

The image processing unit 203 acquires information such as: the distance between the mount point cameras 101 and the electronic component 300, and the tilt/rotation angles of the mount point cameras 101 at the time of imaging the electronic component 300, which is information acquired from the camera control unit 201; and the positional relationship between the two mount point cameras 101, which is pre-established due to the condition in which the multi-nozzle mounting head 110 is installed in. Based on this information, the image processing unit 203 synthesizes the image captured by one of the mount point cameras 101 (see (a) in FIG. 8) with the image captured by the other mount point camera 101 (see (b) in FIG. 8). Moreover, during this synthesis, it is possible to obtain accurate stereoscopic image data of the electronic component 300 (see (c) in FIG. 8) by analyzing the two images in which the state of distortion differs in the same parts of the electronic component 300.

Note that while FIG. 8(c) shows a post-synthesis image of the electronic component 300 viewed from one direction, the synthesized image data includes information of each surface of the electronic component 300 aside from the back side, and thus it is possible to obtain images of the component as viewed from various angles.

In such a manner, it is possible to eliminate regions of the electronic component 300 that cannot be seen at the attachment point (aside from the back side of the component) by synthesizing images obtained from plural directions. Moreover, it is possible to obtain an accurate image of the electronic component 300, in which the distortion has been corrected, which contributes to the accurate judgment of a component being off-position.

In other words, by acquiring images of the mount state simultaneously from plural angles via the two mount point cameras 101, it is possible to assess the position of the electronic component 300 with great accuracy. In addition, it is also possible to detect abnormalities present even in a single surface of the electronic component 300. Furthermore, a stereoscopic image can be obtained, and thus abnormalities such as standing attachment can be detected with great accuracy.

Note that the present embodiment indicates a single embodiment of the present invention, and the inclusion of two mount point cameras 101 denoted here, as well as the abovementioned effects based on the inclusion of two mount point cameras 101, are not intended to limit the scope of the present invention in any way.

For example, it is possible to judge whether the mount state is acceptable based on whether or not the electronic component 300 has been attached (whether or not a component is missing) even in the case where only a single mount point camera 101 is provided in the component mounter 100. Moreover, it is also possible to detect, to a certain degree, standing pickup or the like by comparing the captured image of the electronic component in question to an image of an electronic component in a normal attachment state prepared in advance. In addition, it is possible to detect abnormalities within the field of view of the mount point camera 101 (for example, there is an image of a state of accuracy above a certain threshold) in the case where such abnormalities exist.

Next, descriptions shall be given of the judgment of whether or not a mounting defect has occurred, the mounting defect being an example of a mounting failure, such as the state in which an electronic component 300 has not been attached to the board 120 (referred to hereafter as a “missing component”).

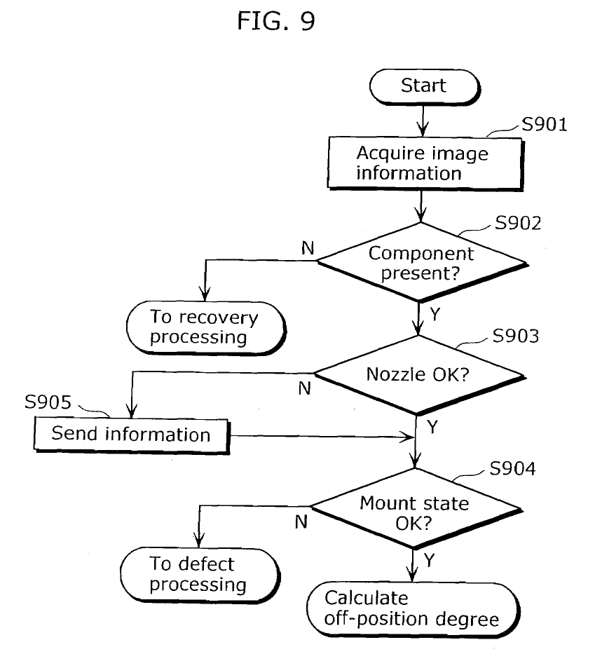

FIG. 9 is a flowchart showing a processing operation for determining a mounting defect.

First, the judgment unit 204 acquires processed image information from the image processing unit 203 (S901) and judges whether or not an image of the component is present in the image information (S902).

In the case where the electronic component 300 is judged by the judgment unit 204 as being not present in the image, or in other words, is judged to be a missing component (N of S902), recovery processing, such as re-attachment, is attempted.

However, when it is judged that the electronic component 300 is present (Y of S902), the state of the pickup nozzle 111 is checked next (S903).

When a bright part in the image of the tip of the pickup nozzle 111 (i.e. solder has built up on the tip of the pickup nozzle 111), an abnormal shape of the tip of the pickup nozzle 111 (i.e. the tip of the pickup nozzle 111 has a deficiency), or the like is detected, it is determined that there is a defect (N of S903), and the information thereof is sent (S905). The pickup nozzle 111 in which the defect has occurred will cause a defective attachment in the next stroke; therefore, the information mentioned here is used to avoid such a defective mount.

Next, the attachment state of the electronic component 300 is judged (S904). The mount state judgment device 200 has acquired, in advance, an image of an electronic component 300 in a normal attachment state; this image is compared with the captured image of the electronic component 300, and when a bright part in the image (the lead area has been captured in the image and unattached leads are judged), an abnormal shape (standing attachment is judged), or the like is detected (N of S904), defect processing is performed.

On the other hand, when the attachment state is judged to be normal (Y of S904), the degree to which the component is off-position is calculated.

In the present embodiment, the abovementioned judgment is performed based on a stereoscopic image of the electronic component 300; for this reason, an abnormality can be detected even when the abnormality (i.e. coplanarity) has occurred, for example, on only one surface of a cubic electronic component 300 (excluding the back side).

Next, calculation of the degree to which a component is off-position and judgment of whether the mount state is acceptable based on the calculated degree to which the component is off-position, which are performed by the judgment unit 204, shall be described.

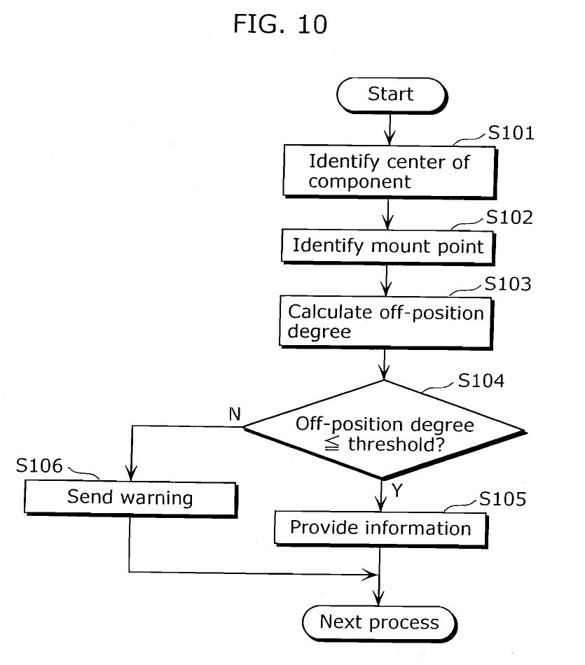

FIG. 10 is a flowchart showing an operation through which the judgment unit 204 calculates the degree to which a component is off-position and through which whether or not the mount state is acceptable is judged based on the degree to which the component is off-position.

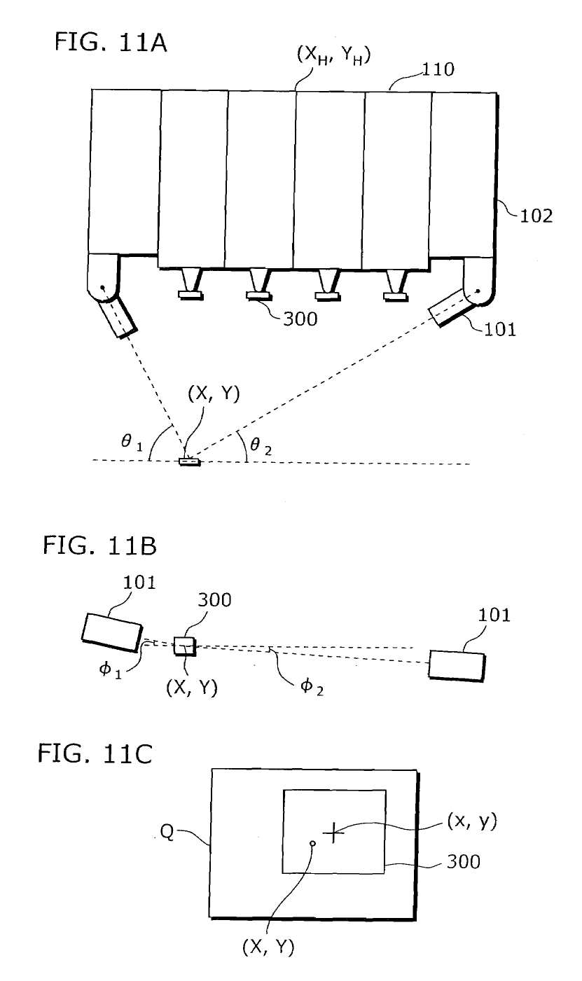

FIG. 11 is a diagram showing a positional relationship for an electronic component 300.

First, the central coordinates (x, y) (the center of mass) of the electronic component 300 (see (c) in FIG. 11), which are found in the horizontal plane of image information Q, are identified based on the image information acquired by the judgment unit 204 (S101).

Next, the coordinates of the mount point (X, Y) in the horizontal plane in the image information Q (see (c) in FIG. 11) are identified based on tilt angles θ1 and θ2 and rotation angles φ₁ and φ₂ of the mount point cameras 101, and the position coordinates (X_{H}, Y_{H}) of the multi-nozzle mounting head 110 (see (a) and (b) in FIG. 11) (S102). It should be noted that the coordinates of the mount point (X, Y) in the horizontal plane are also the coordinates of the central position of the tip of the pickup nozzle 111.

Next, the degree to which the electronic component 300 is off-position is calculated from the central coordinates (x, y) of the electronic component 300 and the coordinates (X, Y) of the mount point (S103).

After this, the degree to which the component is off-position is compared to a pre-set threshold, which is a highest acceptable value for the degree to which a component may be off-position (S104), and in the case where the component is off-position to a degree greater than the threshold (N of S104), warning information is sent (S106).

However, in the case where the component is off-position to a degree that is within the threshold (Y of S104), information indicating the degree to which the component is off-position and that the next processing may be performed is sent (S105). The degree to which the component is off-position is statistically processed and used in feedback for position control.

Through the abovementioned method, it is possible to check whether or not a mount state is acceptable at each instance of an electronic component 300 being attached, and if an attachment defect occurs, recovery processing can be performed for the board 120 currently being mounted with components; therefore, it is possible to suppress occurrences of faulty boards 120 and improve the yield of the mounter. Moreover, as the state of the pickup nozzle 111, which is an instance of the mount state, can be checked, and thus problems arising from using the same pickup nozzle 111 in the next mounting stroke can be discovered in advance. Furthermore, the process of the abovementioned checking is performed while the pickup nozzle 111 retracts back to the multi-nozzle mounting head, and thus it is possible to enjoy the aforementioned effects without having to sacrifice tact time.

In addition, it is possible to quantitatively obtain the degree to which the electronic component 300 is off-position relative to the mount point on the board 120 by imaging the attachment state via plural mount point cameras 101; therefore, it is possible not only to establish the quality of the mount state but also to provide information used in feedback control.

Note that the number of images acquired through the imaging may be only one. In other words, it is also possible to provide only a single mount point camera 101 (one of the two described here). Even when only a single image is acquired, a missing electronic component 300 (that is, a component has been dropped during transport or has been carried back by the multi-nozzle mounting head 110) can still be detected by whether or not the electronic component 300 is present in the image. Furthermore, whether or not solder has built up on the nozzle tip can be judged based on the brightness of the nozzle tip in the image.

Next, descriptions of recovery processing shall be given.

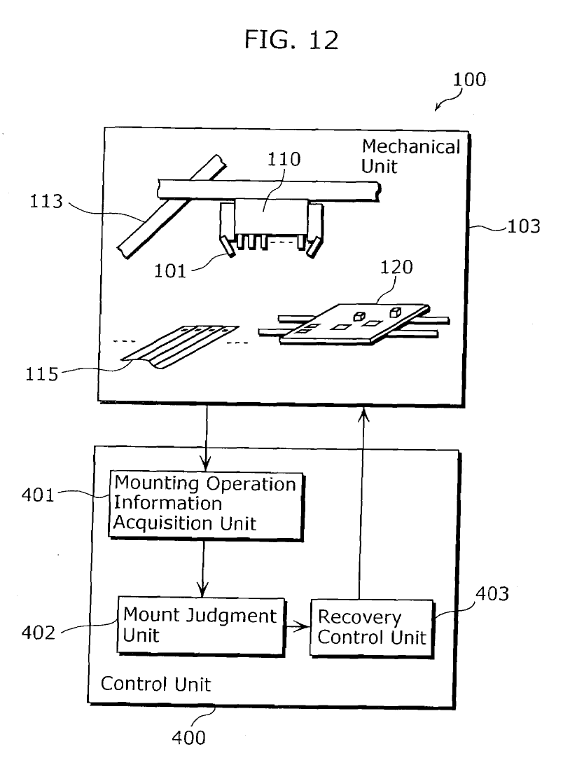

FIG. 12 is a block diagram showing a control unit which controls recovery processing.

As shown in FIG. 12, a control unit 400 includes a mounting operation information acquisition unit 401, a mount judgment unit 402, and a recovery control unit 403.

The mounting operation information acquisition unit 401 is a processing unit that acquires mounting operation information from the mechanical units 103, such as the aforementioned camera control unit 201, position information acquisition unit 202, image processing unit 203, and so on.

The mount judgment unit 402 is a processing unit that judges whether or not a mounting operation has been properly performed, such as whether or not there is a missing component on the board 120, based on the mounting operation information obtained by the mounting operation information acquisition unit 401.

The recovery control unit 403 is a processing unit which, in the case where a mount has been judged by the mount judgment unit 402 to be abnormal, controls the mechanical units 103 so that the component for which the mounting defect occurred is re-mounted before proceeding to the task following the task in which the mounting defect occurred.

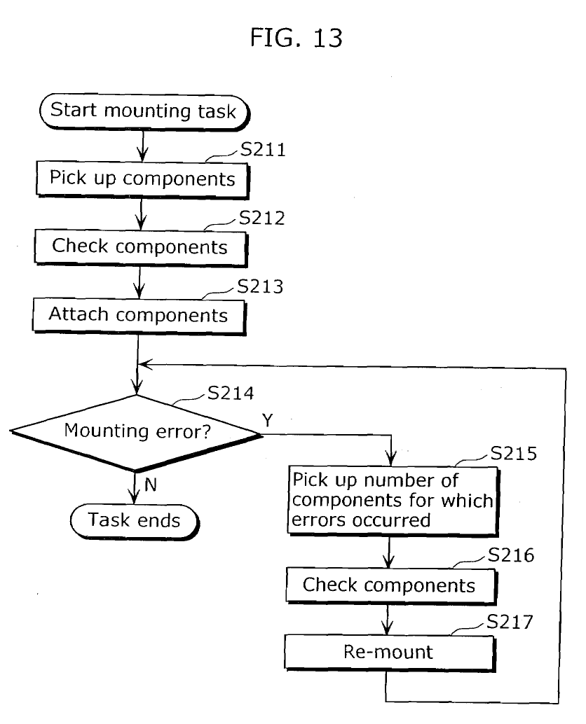

FIG. 13 is a flowchart showing an operation performed in recovery processing.

First, operations included in a single task, or in other words, component pickup (S211), component checking (S212), and component attachment (S213), are performed in accordance with the normal method.

Next, the mount judgment unit 402 judges whether or not a mounting error, such as a missing component, has occurred within the single task that has been performed (S214).

Here, in the case where it is judged that a mounting error has not occurred (N of S214), the task finishes, and the process proceeds to the next task.

However, in the case where it is judged that a mounting error has occurred (Y of S214), the recovery control unit 403 identifies the component (or components, if there are more than one) which could not be mounted as a result of the mounting error occurring, and controls the mechanical unit 103 so as to pick up the same type of component (S215), check the picked-up component (S216), and the re-mount the component (S217).

This recovery processing is effective in that recovery can be performed without disturbing the tasks that have been generated so that the number of times the multi-nozzle mounting head 110 must transit between the component supply unit 15 and the board 120 is kept to a minimum. This recovery processing is even more effective in the case where plural mounting errors (mounting defects) such as missing components have occurred within the same task. To be more specific, the transits performed by the multi-nozzle mounting head 110, which are normally performed each time a mounting error occurs, can be performed collectively in one transit after the task has finished. This makes it possible to keep the number of times the multi-nozzle mounting head 110 must transit for recovery processing to a minimum (once, in the present embodiment), and reduces the amount of time required for recovery processing.

In the present embodiment, imaging performed by the mount point cameras 101 is described as a method for ascertaining the mount state, but it should be noted that the present invention is not limited to this particular setup.

In addition, “mounting error” refers to pickup errors and checking errors in addition to attachment errors.

For example, the mount state may be acquired via a pickup sensor which detects an amount of air flow, degree of vacuity, and so on within the pickup nozzle 111; failure of components to be picked up and mounting defects such as standing pickup may be detected based on air flow and the like which does not occur when the pickup nozzle 111 picks up the electronic component 300 in a normal state.

Moreover, the recognition device 124 may perform imaging and acquire the mount state of the electronic component 300 picked up by the multi-nozzle mounting head 110, rather than the imaging being performed by the mount point cameras 101; cases where the electronic component 300 has not been picked up by the pickup nozzle 111, the electronic component 300 is in a state of standing pickup, a recognition device error occurs and the electronic component is not attached, and so on can be detected thereby.

Furthermore, the mount state may be acquired through the aforementioned pickup sensor or imaging process, and “take-back,” or the situation where an electronic component 300 is still held by the pickup nozzle 111 even after the attachment process has been performed, may be detected as a mounting defect.

The present embodiment aims to fulfill the requirements for implementing the present invention in as specific a form as possible, but the present invention is not intended to be limited to the present embodiment in any way. For example, missing components has been given as a specific example of a mounting defect in the present embodiment, but it goes without saying that the phrase “mounting abnormality” is not intended to be limited only to “missing components.”

By employing the abovementioned apparatus configuration and method, it is possible to monitor and judge, via direct imaging, the states of electronic components 300 (including states in which an electronic component 300 is not present) immediately after being attached to a board 120, without affecting the production time of the board 120. Accordingly, it is possible to perform recovery processing directly on the board 120 for which an error such as a missing component has occurred, which reduces the number of boards 120 on which attachment failures occur, and makes it possible to improve the yield of the mounter.

Note that in the present embodiment, examples of the mount point cameras 101 attached to the multi-nozzle mounting head 110 and the mount point cameras 101 attached to the main body of the component mounter 100 are indicated; however, the present invention is not limited only to imaging performed by such mount point cameras 101. For example, the mount point cameras 101 may be attached to a slave device installed on the multi-nozzle mounting head 110 rather than being directly attached to the multi-nozzle mounting head 110 itself. In other words, the mount point cameras 101 are not particularly limited. Any such device is acceptable as long as it can image the mount state of a component in the interval of time from when the nozzle holding the component begins retracting to when the nozzle reaches its upper limit; for example, a device than can image a component attached at the mount point while the pickup nozzle 111 is ascending.

Furthermore, mounting errors (mounting defects) include not only missing components but also abnormal curvatures in the lead of the electronic component 300 detected by the recognition device 124. The recovery for such a mounting error may include collecting, via the component collection device 123, the electronic components 300 that could not be mounted due to the mounting error, and mounting components of the same type as the electronic components 300 for which the mounting error occurred after the task is finished.

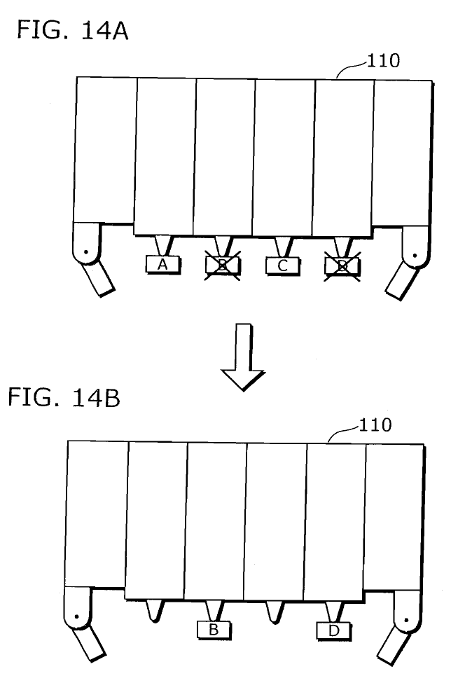

It should be noted that in the case where a failure occurs for two or more components in a task, as shown in (a) in FIG. 14 (components B and D), recovery processing for mounting the components B and D is performed, as shown in (b) of FIG. 14. The order of mounting in this recovery processing may follow a pre-set mounting order (for example, A-B-C-D), hence the components being mounted in B-D order.

Furthermore, the tact times of all possible orders of components for which failure has occurred may be calculated, the order for which the tact time is the shortest may be employed. For example, the tact times of the respective orders B-D and D-B may be compared and the D-B order employed if the D-B order is the shorter of the two.

### Second Embodiment

Next, recovery processing performed by a component mounter 100 in which two multi-nozzle mounting heads 110 mount components on a single board in a cooperative manner (or in an alternating manner) shall be described.

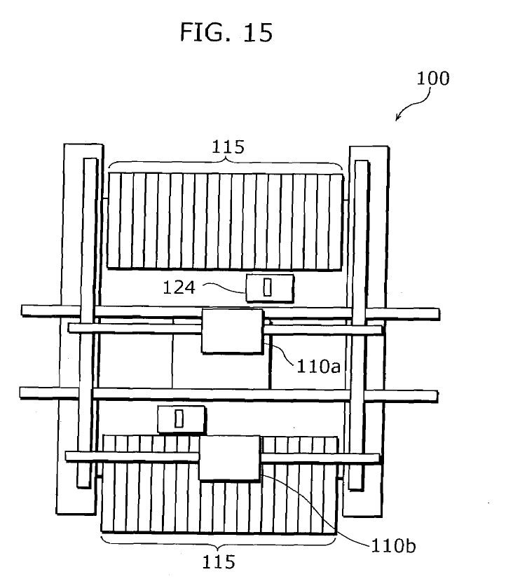

FIG. 15 is a plane view showing the primary configuration of a component mounter.

The component mounter 100 according to the present second embodiment includes two each of component supply units 115, multi-nozzle mounting heads 110, and recognition devices 124 in the front and rear (the top and bottom of FIG. 15). The mounters in the front and the back are independent from one another, and the configuration is such that it is possible for only one mounter to mount electronic components on the board.

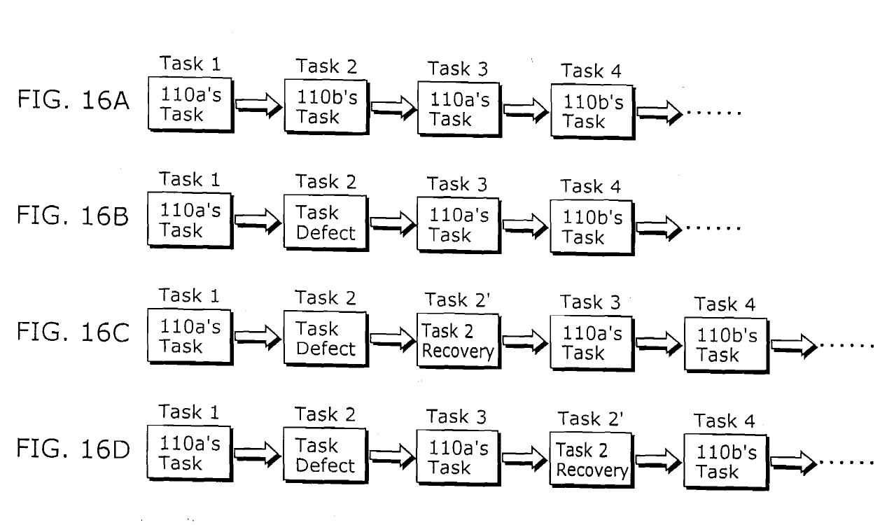

In the case of a component mounter 100 which can perform alternating mounting, such as mentioned above, two multi-nozzle mounting heads 110a and 110b normally perform alternating mounting processes, as can be seen in (a) of FIG. 16. This is because an improvement in throughput can be realized through such an alternating mounting process.

As an example, it is assumed here that a defect occurs in task 2, as shown in (b) of FIG. 16.

In this case, task 2′ must be executed in order to perform recovery processing. Task 2′ is a task (the task shown in (b) of FIG. 14) made up of only components for which mounting defects have occurred (B and D in (a) of FIG. 14, indicated by an “x”) within the task in which the mounting defects occurred (task 2, shown in (a) of FIG. 14).

The timing at which to execute task 2′ for recovery involves putting the multi-nozzle mounting head 110a in standby, without executing task 3, and executing task 2′ via the multi-nozzle mounting head 110b after task 2, as is shown in (c) of FIG. 16. In addition, as shown in (d) of FIG. 16, task 2′ may be executed by the multi-nozzle mounting head 110b after task 3 is performed.

In other words, a first recovery method (the method shown in (c) of FIG. 16) is performing recovery before moving to the task subsequent to the task in which the mounting defect occurred, without making any distinction between the multi-nozzle mounting heads 110a and 110b (or in other words, using either of the multi-nozzle mounting heads). In this case, the multi-nozzle mounting head 110a or 110b that performed the task in which the mounting defect has occurred continues to perform operations, and the multi-nozzle mounting head 110a or 110b which is opposite the multi-nozzle mounting head that is continuing operations stands by until the recovery process finishes. Therefore, while there is the possibility of tact loss occurring at this time, the task following the end of the recovery processing proceeds at the timing determined at the outset.

On the other hand, a second recovery method (the method shown in (d) of FIG. 16) is performing recovery processing after completing the task subsequent to the task in which the mounting defect occurred (in other words, the multi-nozzle mounting head used in the latter task is different from the multi-nozzle mounting head used in the former task). In this case, whichever of the multi-nozzle mounting heads 110a and 110b performed the task in which the mounting defect occurred holds the components that could not be mounted and stands by, and immediately after the mounting performed by the multi-nozzle mounting head 110a or 110b which is opposite the multi-nozzle mounting head that is standing by finishes, recovery processing is performed using the multi-nozzle mounting head for which the mounting error occurred. In other words, recovery processing is performed using the multi-nozzle mounting head for which the mounting defect occurred before that multi-nozzle mounting head proceeds to the next task. Therefore, while there is no tact loss when the mounting error occurs, the subsequent tasks performed by the multi-nozzle mounting head for which the mounting error occurred experience one task's worth of delay, and thus the final task is performed later than was originally set.

Furthermore, the throughput of the situations shown in the aforementioned (c) and (d) may be calculated and the order which is shorter may be employed.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### Industrial Applicability

The present invention is applicable in a component mounter, and particularly in a component mounter which mounts electronic components onto a circuit board.

1. A component mounting method for use in a component mounter which includes a multi-nozzle mounting head for picking up plural components, holding the components at one time, and attaching the picked-up components in sequence on a board, said component mounting method comprising:
acquiring mounting operation information;
judging, based on the acquired mounting operation information, whether or not a component has been mounted properly; and
in the case where the component is judged as not having been mounted properly, performing recovery by re-mounting the component not mounted properly, before moving to the task that follows the task in which the component was not mounted properly,
wherein the task is defined as one iteration of a process that includes the series of pickup, transport, and attachment of a component by a multi-nozzle mounting head.

2. The component mounting method according to claim 1,
wherein in the case where plural components are judged as not having been mounted properly in said judging, in said recovery, the plural components not mounted properly are held and re-mounted collectively after the task in which the improper mounts occurred finishes.

3. The component mounting method according to claim 1,
wherein the component mounter includes two multi-nozzle mounting heads positioned opposite from one another and which pick up plural components at one time and mount the picked-up components on a board, the two multi-nozzle mounting heads mounting the components cooperatively on the board, and
in said recovery, in the case where a component is judged as not having been mounted properly, recovery is performed by re-mounting the component not mounted properly using the multi-nozzle mounting head by which the component was not mounted properly, before moving to the next task performed by the multi-nozzle mounting head in which the improper mount occurred.

4. A component mounting program for use in a component mounter which includes a multi-nozzle mounting head for picking up plural components, holding the components at one time, and attaching the picked-up components in sequence on a board, said program causing a computer to execute the steps of:
acquiring mounting operation information;
judging, based on the acquired mounting operation information, whether or not a component has been mounted properly; and
in the case where the component is judged as not having been mounted properly, performing recovery by re-mounting the component not mounted properly, before moving to the task that follows the task in which the component was not mounted properly,
wherein the task is defined as one iteration of a process that includes the series of pickup, transport, and attachment of a component by a multi-nozzle mounting head.

5. A component mounter which includes a multi-nozzle mounting head for picking up plural components, holding the components at one time, and attaching the picked-up components in sequence on a board, said component mounter comprising:
a mounting operation information acquisition unit operable to acquire mounting operation information;
a mount judgment unit operable to judge, based on the acquired mounting operation information, whether or not a component has been mounted properly; and
a recovery unit operable to, in the case where the component is judged as not having been mounted properly, perform recovery by re-mounting the component not mounted properly, before moving to the task that follows the task in which the component was not mounted properly,
wherein the task is defined as one iteration of a process that includes the series of pickup, transport, and attachment of a component by a multi-nozzle mounting head.
